(19) United States
(12) Patent Application Publication
(10) Pub. No.: US 2008/0105410 A1
(43) Pub. Date: May 8, 2008

(54) HEAT DISSIPATION APPARATUS

(75) Inventors: Ching-Bai Hwang, Tu-Cheng (TW); Jie Zhang, Shenzhen (CN)

Correspondence Address: PCE INDUSTRY, INC.;ATT. CHENG-JU CHIANG, 458 E. LAMBERT ROAD, FULLERTON, CA, 92835, US

(73) Assignee: FOXCONN TECHNOLOGY CO., LTD., Taipei Hsien (TW)

(21) Appl. No.: 11/556,594

(22) Filed: Nov. 3, 2006

(51) Int. Cl. H05K 7/20

(52) U.S. Cl. 165/104.33; 165/122; 361/697

(57) ABSTRACT

A heat dissipation apparatus (10) includes a heat-dissipating fan (14) and a fin assembly (12). The heat-dissipating fan includes a casing (141) and a plurality of blades (142) rotatably received in the casing. The casing defines an air outlet (148) through which an airflow generated by the blades flows. The air outlet has a front side (148b) and a rear side (148a). The airflow first reaches the front side and then flows towards the rear side. The fin assembly is arrangepd at the air outlet of the fan, and includes a plurality of first fins (121) adjacent to the rear side of the air outlet and a plurality of second fins (122) adjacent to the front side of the air outlet. The first fins are integrally formed with the casing of the fan, whilst the second fins consist of a stack of individually formed fins.

### BACKGROUND OF THE INVENTION

1. Field of the Invention

The present invention relates generally to a heat dissipation apparatus, and more particularly to a heat dissipation apparatus for dissipating heat generated by electronic components.

2. Description of Related Art

In nowadays, heat dissipation apparatuses are arranged in electronic products such as computers in order to dissipate heat generated by heat-generating electronic components such as CPUs. The heat dissipation apparatus includes a fan and a fin assembly integrally formed at an air outlet of the fan. The fin assembly thermally connects with the CPU to absorb heat therefrom. The fan provides an airflow flowing through the fin assembly to take the heat away so as to keep the CPU at a normal working temperature.

However, due to the rapid development of the electronics industry, heat dissipation apparatuses with integrally formed fin assemblies can not satisfy the heat dissipation requirements of high frequency products. This is due to the density of fins and width-height ratio of each fin of the integrally formed fin assembly being limited by the techniques used to manufacture them. Increases in the heat dissipating area of the integrally formed fin assembly are thus limited, which also limits improvements in the heat dissipation efficiency of the heat dissipation apparatus. Therefore, the density of the fins and the height-width ratio of each fin of the fin assembly need to be increased to improve the heat dissipation efficiency of the heat dissipation apparatus.

In order to satisfy such requirement, an improved fin assembly having a plurality of stacked fins is provided. The fins of the improved fin assembly are separately manufactured and then stacked together, which makes the density of the fins and the width-height ratio of each fin of the stacked fin assembly higher than that of the fins of the integrally formed fin assembly. The heat dissipation area of the stacked fin assembly is accordingly larger than that of the integrally formed fin assembly. Therefore, the heat dissipation efficiency of the heat dissipation apparatus with stacked fin assembly is better than the heat dissipation apparatus with integrally formed fin assembly. However, the more complicated manufacture of the stacked fin assembly increases the cost of the improved heat dissipation apparatus.

Therefore, a heat dissipation apparatus with a fin assembly having better heat dissipation efficiency than that of the integrally formed fin assembly and lower cost than that of the stacked fin assembly is needed.

### SUMMARY OF THE INVENTION

The present invention relates to a heat dissipation apparatus for dissipating heat generated by an electronic component. According to a preferred embodiment of the present invention, the heat dissipation apparatus includes a heat-dissipating fan and a fin assembly. The heat-dissipating fan includes a casing and a plurality of blades rotatably received in the casing. The casing defines an air outlet through which an airflow generated by the blades flows. The air outlet has a near side and a far side. The airflow first reaches the near side and then flows towards the far side. The fin assembly is arranged at the air outlet of the fan, and includes a plurality of first fins adjacent to the far side of the air outlet and a plurality of second fins adjacent to the near side of the air outlet. The first fins are integrally formed with the casing of the fan by die casting, whilst the second fins are provided as a stack of individually formed fins.

Other advantages and novel features of the present invention will become more apparent from the following detailed description of preferred embodiment when taken in conjunction with the accompanying drawings, in which:

### BRIEF DESCRIPTION OF THE DRAWINGS

FIG. 1 is an exploded, isometric view of a heat dissipation apparatus according to a preferred embodiment of the present invention;

FIG. 2 is an assembled view of FIG. 1;

FIG. 3 is a partly assembled view of FIG. 1, but viewed from another aspect; and

FIG. 4 is a top view of FIG. 2, with a top cover thereof being removed.

### DETAILED DESCRIPTION OF THE INVENTION

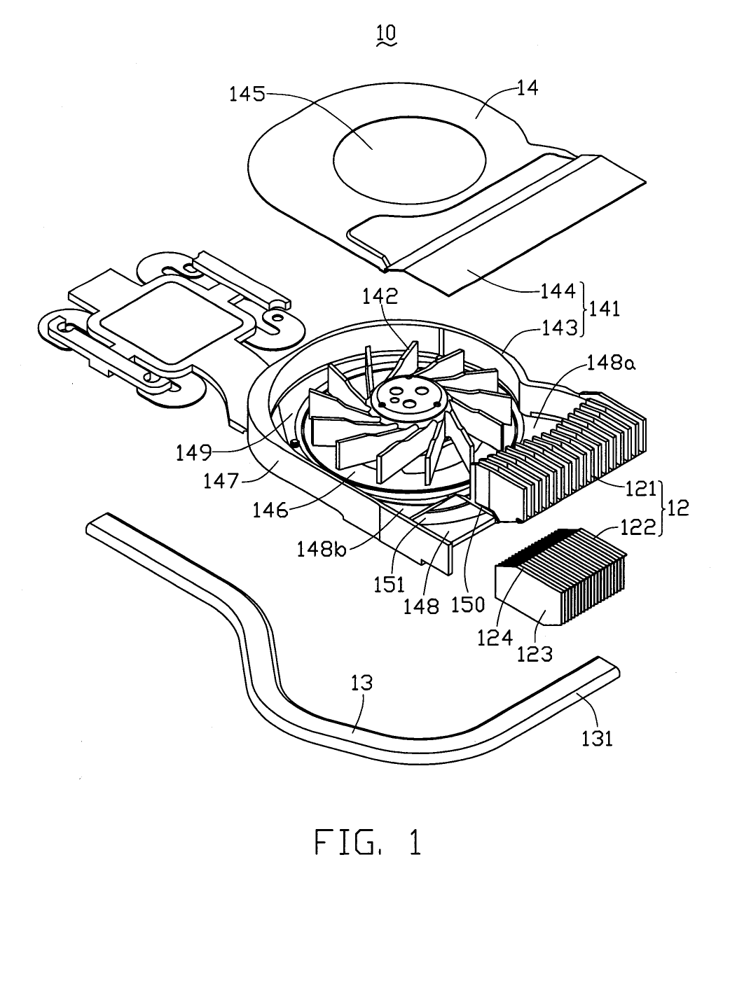

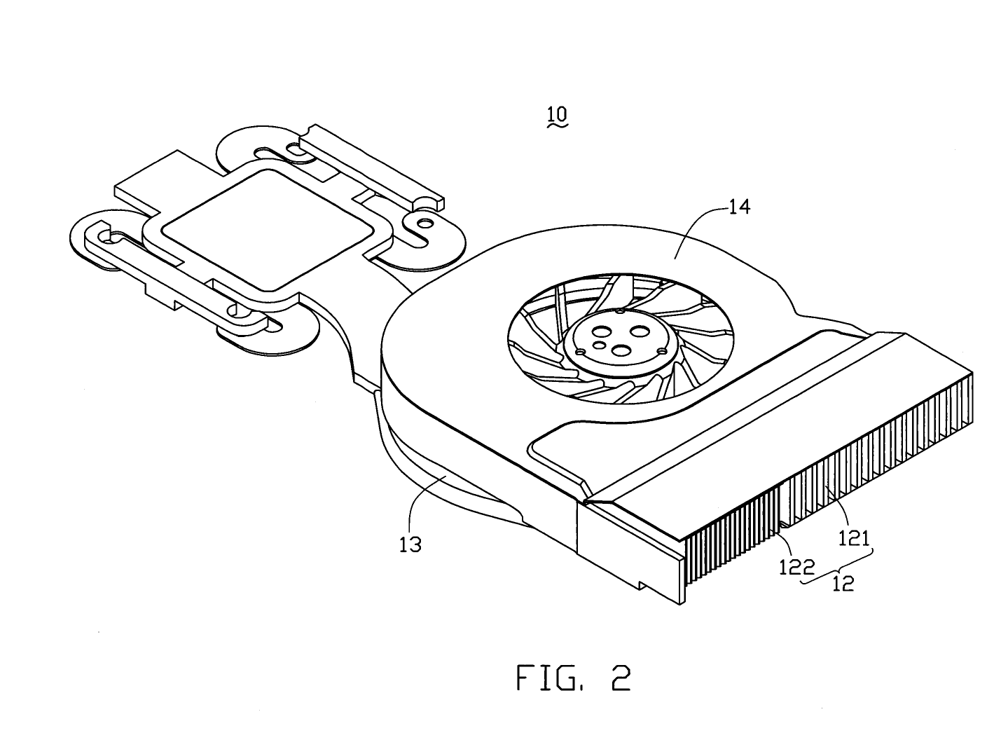

FIGS. 1 to 3 show a heat dissipation apparatus 10 according to a preferred embodiment of the present invention. The heat dissipation apparatus 10 includes a fin assembly 12, an arc shaped flat heat pipe 13 connecting the fin assembly 12 with a heat-generating electronic component (not shown) to transfer heat therebetween, and a heat-dissipating fan 14 for providing an airflow flowing through the fin assembly 12 to take the heat away.

The heat-dissipating fan 14 is a centrifugal blower which enables the airflow to have a high air pressure. The heat-dissipating fan 14 includes a casing 141, a stator (not shown) mounted in the casing 141, and a rotor including a plurality of blades 142 rotatably disposed around the stator for generating an airflow.

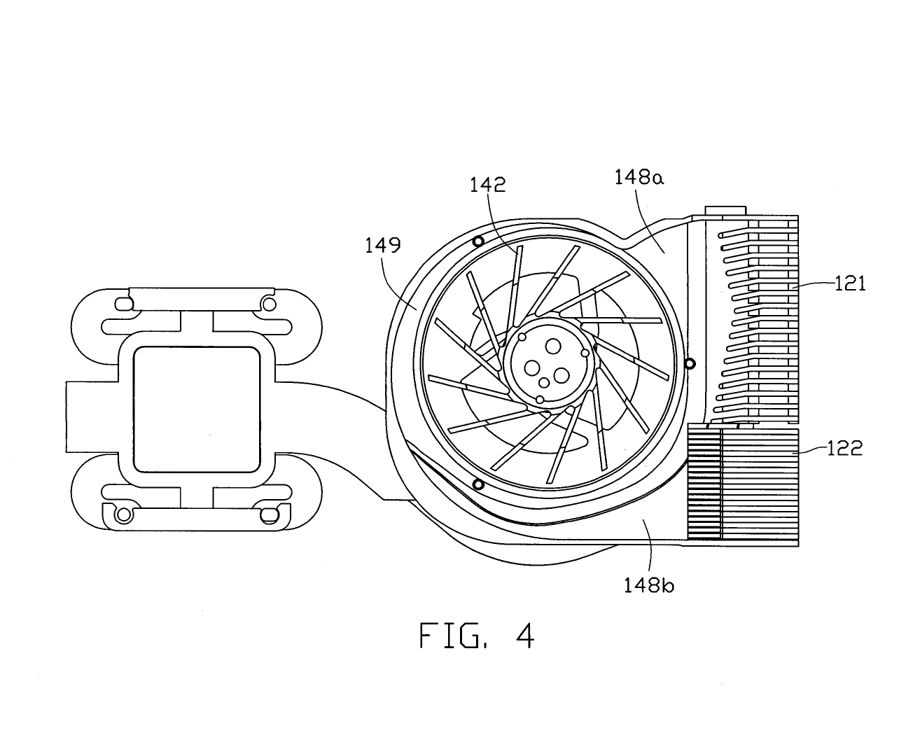

The casing 141 includes a bottom housing 143 and a top cover 144 mounted on the bottom housing 143. The top cover 144 is a plate, which defines an air inlet 145 at a middle portion thereof. The bottom housing 143 includes a flattened base 146, and an arc-shaped sidewall 147 perpendicular to the top cover 144 and the base 146 of the bottom housing 143. The sidewall 147 of the bottom housing 143 defines a linear-shaped air outlet 148 therein. An air channel 149 is formed between free ends of the blades 142 and an inner surface of the sidewall 147 of the bottom housing 143. A width of the air channel 149 is gradually increased along a counterclockwise direction as viewed from FIG. 4 so as to increase the pressure of the airflow, wherein the blades 142 rotate counterclockwise. During operation of the heat-dissipating fan 14, the airflow is driven to first flow toward a front side 148b of the air outlet 148 and then toward a rear side 148a thereof, whereby the airflow leaves the air outlet 148 and the fin assembly 12 to take heat away from the fin assembly 12. The airflow adjacent to the front side 148b of the air outlet 148 has a larger air pressure and flow rate than that of the airflow adjacent to the rear side 148a of the air outlet 148. A top portion of the base 146 of the heat-dissipating fan 14 defines a rectangular shaped groove 150 adjacent to the front side 148b of the air outlet 148, whilst a bottom portion of the base 146 defines an arc shaped channel 151 for receiving the heat pipe 13 therein. The channel 151 has a predetermined depth so that the channel 151 communicates with the groove 150 at a bending portion thereof.

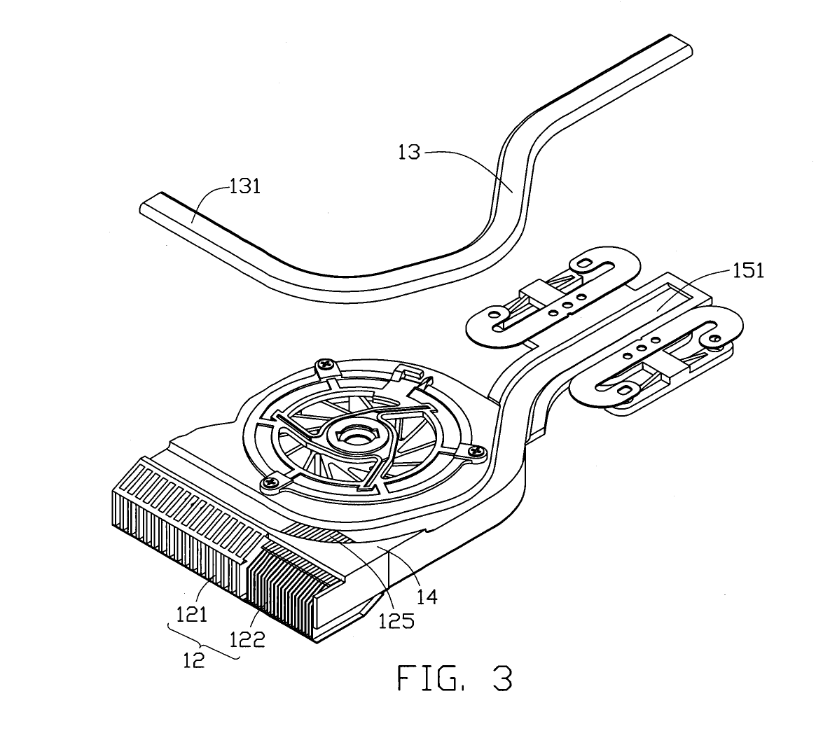

The fin assembly 12 is linear-shaped in profile to match with the air outlet 148 of the heat-dissipating fan 14. The fin assembly 12 includes a plurality of first and second fins 121, 122. The first and second fins 121, 122 are arranged along the air outlet 148 of the heat-dissipating fan 14. An arrangement length (i.e., length of space occupied by the fins perpendicular to the airflow direction) of the second fins 122 is substantially ½ of an arrangement length of the first fins 121. The first fins 121 are integrally formed with the bottom housing 143 of the heat-dissipating fan 14 by die casting of aluminum, magnesium or zinc, and are disposed adjacent to the rear side 148a of the air outlet 148. A height-width ratio of each of the first fins 121 is smaller than that of each second fin 122. A distance between two adjacent first fins 121 is 1.5 mm and a width of each first fin 121 is 1.0 mm. The second fins 122 consist of a stack of individually formed fins stacked along a predetermined direction and positioned in the groove 150 of the bottom housing 143 of the heat-dissipating fan 14. Each of the second fins 122 includes a rectangular shaped main body 123 and two flanges 124 perpendicularly and backwardly extending from upper and bottom ends of the main body 123. When the second fins 122 consist of a stack of individually formed fins, the flanges 124 of a front second fin 122 abut against the main body 123 of a rear second fin 122 so as to maintain a distance therebetween. Alternatively, the front second fin may include a clasping structure, whilst the rear second fin may include a receiving structure for receiving the clasping structure therein, to clip the front second fin onto the rear second fin so as to assemble the second fins together. A distance between two adjacent second fins 122 is 1.1 mm and a width of each second fin 122 is 0.2 mm. Both the distance and the width of the second fins are smaller than those of the first fins 121, so that the second fins 122 have a greater density than the first fins 121. A total area of the second fins 122 arranged at a predetermined length is larger than that of the first fins 121 arranged thereat. Therefore, a heat dissipation efficiency of the second fins 122 at the predetermined length is better than that of the first fins 121 thereat. The flanges 124 at the bottom ends of the second fins 122 cooperatively define a planar surface 125 (FIG. 3) contacting with an upper surface of the base 146 of the heat-dissipating fan 14. A condenser section 131 of the heat pipe 13 is extended to contact a bottom of the fin assembly 12 including the first fins 121 and the second fins 122 so that heat absorbed by an evaporator section (not labeled) of the heat pipe 13 from the heat-generating electronic component can be effectively transferred to the fin assembly 12.

In the present invention, the second fins 122 and the first fins 121 are separately disposed at the front and rear sides 148b, 148a of the air outlet 148 to exchange heat with the airflow flowing therethrough. The airflow adjacent to the front side 148b of the air outlet 148 has larger air pressure and flow rate than the airflow adjacent to the rear side 148a of the air outlet 148, whilst the second fins 122 has a better heat dissipation efficiency than the first fins 121. Therefore, the heat carried by the second and the first fins 122, 121 can be justly dissipated by the airflow flowing through the front and rear sides 148b, 148a of the air outlet 148. This increases the utilization rate and prevents waste of the airflow. Moreover, the usage of second fins 122 causes the heat dissipation efficiency of the present heat dissipation apparatus 10 to be better than the heat dissipation apparatus purely with integrally formed fin assembly. In addition, the manufacture of the first fins 121 reduces the cost of the entire fin assembly 12 of the heat dissipation apparatus 10. Accordingly, the cost of the present heat dissipation apparatus 10 is lower than the heat dissipation apparatus purely with stacked fin assembly. Thus, the present heat dissipation apparatus 10 has a better performance-to-price ratio than the heat dissipation apparatus purely with integrally formed fin assembly and the heat dissipation apparatus purely with stacked fin assembly.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat dissipation apparatus comprising:
a heat-dissipating fan comprising a casing and a plurality of blades rotatably received in the casing, the casing defining an air outlet through which an airflow generated by the blades flows, the air outlet having a near side and a far side, the airflow first reaching the near side and then the far side; and
a fin assembly arranged at the air outlet of the fan, comprising a plurality of first fins adjacent to the far side of the air outlet and a plurality of second fins adjacent to the near side of the air outlet, the first fins being integrally formed with the casing of the fan as a monolithic piece, the second fins being provided as a stack of individually formed fins.

2. The heat dissipation apparatus as described in claim 1, wherein the casing further defines an air inlet perpendicular to the air outlet.

3. The heat dissipation apparatus as described in claim 2, wherein the air inlet is defined in a top wall of the casing, whilst the air outlet is defined in a sidewall of the casing.

4. The heat dissipation apparatus as described in claim 1, wherein a distance between two adjacent second fins is smaller than that between two adjacent first fins.

5. The heat dissipation apparatus as described in claim 1, wherein a width-height ratio of each of the first fins is larger than that of each of the second fins.

6. The heat dissipation apparatus as described in claim 1, wherein an arrangement length of the second fins is substantially ½ of an arrangement length of the first fins.

7. The heat dissipation apparatus as described in claim 1, wherein the casing defines a groove for positioning the second fins therein.

8. The heat dissipation apparatus as described in claim 7 further comprising a heat pipe thermally contacting with the fin assembly, and the casing of the heat-dissipating fan defines a channel for receiving the heat pipe therein.

9. The heat dissipation apparatus as described in claim 8, wherein the channel communicates with the groove at a portion thereof.

10. A heat dissipation apparatus comprising:
a centrifugal blower comprising a casing and a plurality of blades rotatably received in the casing for providing an airflow, the casing defining an air inlet and an air outlet therein, the air outlet having a near side and a far side, an airflow generated by the fan first flowing to the near side and then to the far side; and
a fin assembly comprising a plurality of first fins adjacent to the far side of the air outlet and a plurality of second fins adjacent to the near side of the air outlet, the second fins having a larger density than the first fins.

11. The heat dissipation apparatus as described in claim 10, wherein the first fins are integrally formed with the casing of the fan as a monolithic piece, whilst the second fins are provided as a stack of individually formed fins.

12. The heat dissipation apparatus as described in claim 10, wherein the casing defines a groove for positioning the second fins therein.

13. The heat dissipation apparatus as described in claim 12 further comprising a heat pipe for connecting the fin assembly with a heat generating electronic component, the casing of the heat-dissipating fan defining a channel for receiving the heat pipe therein.

14. The heat dissipation apparatus as described in claim 13, wherein the channel communicates with the groove at a portion thereof.

15. The heat dissipation apparatus as described in claim 10, wherein an arrangement length of the second fins is substantially ½ of an arrangement length of the first fins.

16. The heat dissipation apparatus as described in claim 10, wherein a width-height ratio of each of the first fins is larger than that of each of the second fins.

17. A heat dissipation apparatus comprising:
a fan comprising a casing defining an inlet and an outlet, wherein the fan generates an airflow flowing from the inlet through the outlet; and
a fin assembly for thermally connecting with a heat-generating electronic component to absorb heat therefrom, the fin assembly being positioned at the outlet of the casing of the fan and having first fins integrally formed with the casing of the fan as a monolithic piece and second fins which are individually formed from the casing of the fan.

18. The heat dissipation apparatus as described in claim 17, wherein two adjacent first fins are spaced from each other a distance which is larger than that between two adjacent second fins.

19. The heat dissipation apparatus as described in claim 18, wherein each of the first fins has a width which is larger than that of each of the second fins.

20. The heat dissipation apparatus as described in claim 17 further comprising a heat pipe for thermally connecting the fin assembly with the heat-generating electronic component.
